(19) United States
(12) Patent Application Publication
(10) Pub. No.: US 2023/0333185 A1
(43) Pub. Date: Oct. 19, 2023

(54) SYSTEM, METHOD AND COMPUTER-ACCESSIBLE MEDIUM FOR SEPARATING FAT AND WATER IN MAGNETIC RESONANCE IMAGING USING FREQUENCY SWEEP RADIOFREQUENCY SATURATION PULSES

(71) Applicant: New York University, New York, NY (US)

(72) Inventors: KAI TOBIAS BLOCK, Brooklin, NY (US); Ruoxun Zi, New York, NY (US); Hersh Chandarana, Scardale, NY (US)

(21) Appl. No.: 18/135,990

(22) Filed: Apr. 18, 2023

Related U.S. Application Data
(60) Provisional application No. 63/331,918, filed on Apr. 18, 2022.

(51) Int. Cl. G01R 33/48

(52) U.S. Cl. CPC G01R 33/4828

(57) ABSTRACT

Exemplary systems, methods and computer-accessible medium according to exemplary embodiments of the present disclosure can separate fat and water in magnetic resonance imaging using frequency sweep radiofrequency saturation pulses. In an exemplary procedure, periodic RF saturation pulses with varying frequency offset from a water resonance frequency with at least two different offsets are emanated. In another exemplary procedure, the signal response to saturation at different frequencies on a voxel-by-voxel basis can be analyzed.

### CROSS-REFERENCE TO RELATED APPLICATION(S)

This application relates to and claims priority from U.S. Provisional Patent Application Ser. No. 63/331,918, filed Apr. 18, 2022, the disclosure of which is incorporated herein by reference in its entirety.

### FIELD OF THE DISCLOSURE

The present disclosure relates generally to magnetic resonance imaging, and more specifically, to exemplary embodiments of exemplary system, method and computer-accessible medium for separating fat and water in magnetic resonance imaging using frequency sweep radiofrequency saturation pulses.

### BACKGROUND INFORMATION

In magnetic resonance imaging (“MRI”), sometimes tomographic images of a subject are obtained with a continuously repeated pulse-sequence program that generates a radiofrequency (“RF”) pulse to excite nuclei in the tissue of interest, and optionally followed by a readout module to sample the “magnetic resonance” of the nuclei. In some MRI applications, only the protons may be used for the excitation and signal detection. Therefore, the frequency of the RF excitation pulse can be set to the protons' Larmor frequency ω_H:

107 _H=γ_H·B,

where γ_H is the gyromagnetic ratio of protons (MHz/T) and B is the magnetic field strength. Because the Larmor frequency can be dependent on the field strength that the protons experience (which can vary between MRI magnets and drift over time), a spectroscopic calibration procedure can be performed prior to each MRI scan to measure the frequency corresponding to water in the subject's body. In addition to water, protons can be contained in fatty acids of the body. Fat protons likely have a slightly lower resonance frequency due to stronger shielding effects by the electron clouds. The frequency difference between water and fat protons is called “chemical shift”. Although the measured resonance frequency of water can be used for the RF excitation pulse, typically also fat protons get excited because the spectral footprint of typical RF excitation pulses can be so wide that it exceeds the chemical-shift distance. Thus, protons from both water and fat contribute to the sampled signal and become visible in the reconstructed images.

Certain MRI applications require that only water protons contribute to the image information. Such scans are referred to as “fat-suppressed” or “fat-separated” MRI acquisition and are needed for various reasons. For example, lesion categorization may require assessing if lesions contain water (e.g., cysts) or fat (e.g., lipomas). Because both fat and water are bright on regular MRI scans, fat-suppressed scans may be helpful for classifying the lesions. As another example, fat can be very bright on MRI images and can lower the conspicuity of subtle findings in the water signal. Therefore, fat-suppressed acquisition may be used for some examinations. As yet another example, due to the lower resonance frequency, the phase of signal components induced by fat can disperse from water components after the excitation, resulting in image artifacts for scans with long readouts or non-Cartesian geometry. As workaround, such scans can be done with fat suppression. As yet another example, diagnosis and staging of certain diseases (e.g., fatty liver disease) may require quantitative assessment of the tissue fat content, which is possible by comparing regular and fat-suppressed acquisition.

Different concepts have been described to achieve fat suppression or fat separation in MRI (See, e.g., Bley-2010). For example, fat saturation techniques, such as CHESS, can use spectrally selective RF pulses that are centered on the resonance frequency of fat to excite only the fat protons. After excitation, the fat signal can be de-phased by switching strong magnetic gradient fields, known as spoiler gradients. Subsequent readouts can be therefore free from spurious fat signals until the fat protons have relaxed to the lower energy state and can be excited again. To prevent the saturation RF pulses from eliminating the water signal, long pulse waveforms can be used that provide sufficiently narrow spectral selectivity. Due to the long duration of such pulse waveforms, saturation pulses may typically not be played for every readout but only after n readout repeats, which is commonly referred to as “quick fat-sat”.

As another example, inversion recovery techniques for fat suppression, such as the STIR method, can generate a magnetization preparation RF pulse that flips the magnetization by 180 degrees, followed by a wait period that is selected such that the longitudinal magnetization of fat crosses zero in the moment when imaging data is acquired. Therefore, only water protons may get excited by the following RF excitation pulse.

As yet another example, hybrid techniques, such as SPIR and SPAIR, combine the principles of frequency-selective fat saturation and inversion recovery fat suppression by using a frequency-selective inversion recovery pulse, followed by a spoiler gradient (See, e.g., Lauenstein-2008).

As yet another example, water-selective excitation uses RF excitation pulses with sufficiently narrow spectral profile to avoid excitation of fat protons. Because suited pulse waveforms have long duration and must be played for every readout, the overall scan time can be significantly increased, which may limit applicability.

As yet another example, phase-based techniques for fat/water separation, such as the Dixon method and variations, use multiple readouts after each RF excitation pulse, which can be timed such that data is acquired when fat and water components are in phase and when they have opposed phases. The data can be combined such that either the fat signal or water signal cancel out, resulting in water-only or fat-only images.

These techniques are available on clinical MRI devices with magnetic field strength of 1.5 or 3 Tesla and can be used in clinical examination protocols.

Recently, a new generation of MRI systems has been introduced with low magnetic field strength, ranging from 0.55 Tesla (See, e.g., Chandarana-2021) down to only 0.055 Tesla (See, e.g., Lui-2021). Such low-field scanners use cheaper components and have reduced siting requirements, making examinations more affordable and accessible. However, the low magnetic field strength may lead to challenges for fat suppression because the chemical shift, i.e., the spectral separation between the water and fat protons, may decrease linearly with the field strength. As result, some of the existing fat-suppression techniques are ineffective or lead to longer scan times when used at low field strength.

For example, spectral fat-saturation methods may require an RF pulse with much narrower spectral selectivity to saturate the fat while avoiding saturation of the water. This may increase pulse durations. Moreover, if the static magnetic field B0 suffers from local inhomogeneities due to magnet shimming problems or patient-specific susceptibility effects, e.g., near skinfolds, either the fat saturation may fail locally, or the water signal may get saturated. Both effects can be problematic for clinical use.

Phase-based methods, on the other hand, may require longer wait times to capture the in- and opposed-phase conditions during the readout because the speed of the phase drift can decrease with the chemical shift. Such drastically prolongated readout times can make certain acquisition types difficult, including breath-hold scans that may have to be acquired in a time during which average patients can suspend respiration, as well as balanced steady-state free precession (bSSFP) acquisition (See, e.g., Bieri-2013), which may require rapid sequence repetition to avoid phase drifts from field inhomogeneities that would lead to local signal cancellation.

Thus, it may be beneficial to provide an exemplary system, method, and computer-accessible medium for separating fat and water in Mill which can overcome at least some of the deficiencies described herein above.

### SUMMARY OF EXEMPLARY EMBODIMENTS

Exemplary systems, methods and computer-accessible medium, according to exemplary embodiments of the present disclosure can address the challenges that may arise when using conventional fat suppression methods at low field strength. Exemplary systems, methods and computer-accessible medium, according to exemplary embodiments of the present disclosure can relate to an exemplary procedure, system, method and computer-accessible medium for facilitating fat suppression. In exemplary embodiments of the present disclosure, instead of repeatedly generating the same RF saturation pulse with constant frequency offset from the water resonance frequency, as done for conventional fat saturation, exemplary systems, methods and computer-accessible medium, according to exemplary embodiments of the present disclosure can generate RF saturation pulses with a range of different frequency offsets, centered around the fat resonance frequency, while continuously acquiring imaging data. This procedure can be referred to as “frequency sweep RF saturation”. In exemplary embodiments of the present disclosure, after the acquisition, the data can be reconstructed into separate image volumes for each frequency offset, so that a spectral dimension can be obtained that reflects the tissue response to RF saturation at the respective frequency offsets.

In exemplary systems, methods and computer-accessible medium, according to exemplary embodiments of the present disclosure, such images can be used to extract a characteristic signal-response curve for each voxel of the imaging volume, which can allow determining the fat and water content in the voxel. Accordingly, in exemplary embodiment of the present disclosure, instead of relying on the precision and effectiveness of a single RF saturation pulse, which may be expected to diminish in areas with strong local field homogeneities and for field strengths with narrow spectral separation between fat and water, exemplary systems, methods and computer-accessible medium according to exemplary embodiments of the present disclosure can utilize a response curve generated from multiple saturation frequencies for classifying—or even quantifying—the tissue content. In exemplary embodiments, this may relax the accuracy requirement for individual saturation pulses because it may not be notable that the fat signal gets fully suppressed by one of the saturation pulses. Therefore, in exemplary embodiments of the present disclosure, shorter pulse waveforms with less optimal spectral selectivity can be used. Moreover, use of a range of saturation frequencies can make the procedure robust to inhomogeneities of the static magnetic field BO because it may not rely on a global, pre-selected frequency offset for the fat protons.

Some data acquisition for a range of different saturation frequencies may result in an increase of the acquisition time proportional to the number of sampled frequency offsets. This would make the scan time undesirably long and limit clinical applicability. To keep the scan time relatively short, the exemplary systems, methods and computer-accessible medium, according to exemplary embodiments of the present disclosure can use an undersampling strategy that can acquire only incomplete data for each frequency offset and can apply a compressed-sensing reconstruction algorithm (See, e.g., Block-2007, Lustig-2007) to take advantage of correlations that may exist between the data acquired for the different frequency offsets. This can be possible because changes in the saturation frequency may affect only the image contrast while the object location and edge structures remain invariant across data points, resulting in considerable degree of correlation. Exploiting these correlations through use of compressed sensing can keep the scan time in the same magnitude as an acquisition with regular fat suppression.

In exemplary systems, methods and computer-accessible medium according to exemplary embodiments of the present disclosure data for each offset can be acquired using radial sampling of k-space, e.g., sampling of the data space in a spoke-wheel-like fashion (See, e.g., Lauterbur-1973, Block-2014). Radial sampling of k-space can provide higher robustness to motion, so that scans can be obtained during free breathing of the patient (Chandarana-2011). In addition to eliminating the need for breath-holding, radial sampling can offer advantageous undersampling properties. Because the radial spokes may overlap in the center of k-space, in exemplary embodiments of the present disclosure, images can be reconstructed for arbitrary degrees of undersampling, so that the undersampling factor can be selected in a continuous manner (e.g., 10%, 15%, 33%, 50%, etc.). Moreover, when using radial sampling to acquire a series of data points, in exemplary embodiments of the present disclosure, the radial spokes can be ordered such that each data point uses a set of sampling locations that can differ from the other data points, enabling creation of a densely sampled composite dataset that averages over all saturation frequencies. Hence, in exemplary embodiments, both a densely sampled composite image as well as an image series that reveals the response to frequency-dependent RF saturation can be generated from the same acquisition.

After reconstructing the image series using a compressed-sensing method (see, e.g., Block-2007, Lustig-2007), such as the GRASP technique (see, e.g., Feng-2014, Feng-2016), signal response curves can be extracted for each voxel. Such curves can be used in multiple procedures to classify the fat content of the voxels. One exemplary procedure can involve fitting an equation based on the expected saturation profile, which can be derived from the waveform of the saturation pulse, to the experimentally obtained curve and to determine the frequency of maximum signal suppression from the curve fit. This exemplary frequency can then be used to classify the voxel into containing predominantly fat or predominantly water. Because the frequency of maximum saturation gets shifted in the presence of BO field inhomogeneities, in exemplary embodiments, neighborhood relationships can be used to compensate for B0 fluctuations as B0 variations can be expected to be spatially smooth. In another exemplary procedure, the classification information can be used to convert the acquired data into separate water-only and fat-only composite images.

In exemplary procedures, a two-component model can be fitted to the observed signal-response curves, which provides quantitative estimates of the water and fat fractions contained in each voxel and may be used to detect pathologic fat infiltration of tissue, such as fatty liver disease. This can be achieved by superimposing the assumed signal-response functions for water and fat components, shifted by the expected spectral separation for the field strength, and by including, e.g., a B0 parameter to account for overall curve shifts resulting from local B0 field inhomogeneities. In an exemplary procedure according to an exemplary embodiment of the present disclosure, the information can be combined into composite water-only and fat-only images to provide images with comparable appearance to conventional fat-suppressed or fat-separated images.

According to additional exemplary embodiments of the present disclosure, exemplary method, system and computer-accessible medium can be provided for separating fat from water contributions in at least one magnetic resonance (“MR”) image. For example, periodic RF saturation pulses can be provided with varying frequency offset from a water resonance frequency with at least two different offsets. The signal response to saturation can be analyzed at different frequencies on a voxel-by-voxel basis. Further, based on the analyzed signal response, the fat can be separated from the water contributions in the at least one MR image.

For example, the analysis of the signal response can comprise (i) the use of a signal-response profile to classify each voxel into substantially containing fat and substantially containing water, (ii) the use of a signal-response profile to quantitatively estimate a percentage of fat and a percentage of water contained in each voxel, or (iii) radial sampling of k-space to acquire data for different frequency offsets of the RF saturation pulse. It is possible to also sample radial views such that acquired view angles differ between frequency offsets and the radial views are combined to form a dense set of radial views.

In a further exemplary embodiment of the present disclosure, the analysis of the signal response can comprise under-sampling data for each frequency offset by skipping sampling steps to shorten an acquisition duration. It is also possible to utilize a compressed-sensing principle to recover images for different frequency offsets by utilizing correlations between the data from adjacent frequency offsets. In addition, it is possible to utilize an XD-GRASP procedure and a compressed-sensing procedure for radial sampling to recover images for all frequency offsets. The offset frequency can be treated as extra dimension for the XD-GRASP procedure. According to a further exemplary embodiment of the present disclosure, it is possible to perform a correlation of adjacent frequency offsets by penalizing an L1 norm or an L2 norm of the finite difference of the image intensity between a current frequency offset and at least one of the adjacent frequency offsets on a voxel-by-voxel basis.

According to yet another exemplary embodiment of the present disclosure, the analysis of the signal response can comprise combining the data acquired for the different frequency offsets into at least one of (i) a composite image that shows only water contributions, or (ii) a composite image that shows only the fat contributions. In addition or alternatively, the analysis of the signal response can comprise fitting an analytical signal-response model to an experimentally observed signal-response curve to quantitatively estimate a fat fraction in each voxel. Alternatively, the analysis of the signal response can fitting an analytical signal-response model to an experimentally observed signal-response curve to quantitatively and jointly estimate a fat fraction and a static magnetic field deviation B₀ in each voxel.

In yet another exemplary embodiment of the present disclosure, the analysis of the signal response can comprise using neighborhood relationships to enforce smooth spatial change of an estimated static magnetic field deviation map B0. The separating procedure can comprise calculating a phase difference between the fat and the water. The phase difference between the fat and the water can be incorporated into an extended two-component fitting model. The extended two-component fitting model can be based on at least one of a fat intensity or a water intensity. The extended two-component fitting model can also be based on at least an overall curve-shift from local B0 inhomogeneities or residual noise.

These and other objects, features and advantages of the exemplary embodiments of the present disclosure will become apparent upon reading the following detailed description of the exemplary embodiments of the present disclosure, when taken in conjunction with the appended claims.

### BRIEF DESCRIPTION OF THE DRAWINGS

Further objects, features and advantages of the present disclosure will become apparent from the following detailed description taken in conjunction with the accompanying Figures showing illustrative embodiments of the present disclosure, in which:

FIG. 1 is an exemplary pulse sequence diagram of an exemplary three-dimensional (3D) bSSFP MRI sequence with a radial sampling according to exemplary embodiments of the present disclosure;

FIG. 2 is an exemplary pulse sequence diagram of an exemplary 3D GRE MRI sequence with the radial sampling according to exemplary embodiments of the present disclosure;

FIG. 3 is a diagram of an exemplary stack-of-stars acquisition scheme which uses radial sampling in the kx and ky plane and regular Cartesian sampling in the kz direction according to exemplary embodiments of the present disclosure;

FIG. 4 is an exemplary graph of timing of radio frequency (RF) pulses which can be used for the exemplary 3D bSSFP sequence according to exemplary embodiments of the present disclosure;

FIG. 5 is an exemplary diagram of an exemplary frequency sweep RF saturation principle;

FIGS. 6(a) and 6(b) are a set of illustrations of an exemplary abdominal free-breathing scan providing multiple illustrations with the exemplary 3D bSSFP sequence at 0.55 Tesla according to exemplary embodiments of the present disclosure;

FIG. 7 is an exemplary graph providing an exemplary signal-response curve extracted from the voxel of a phantom scan according to exemplary embodiments of present disclosure;

FIG. 8 is an exemplary graph providing exemplary results of analytic equations that can be used for fitting the experimental data according to exemplary embodiments of the present disclosure;

FIG. 9 illustrates exemplary abdominal free-breathing data obtained with the 3D bSSFP sequence at 0.55 Tesla according to exemplary embodiments of the present disclosure;

FIG. 10 is a set of images with associated exemplary graphs providing exemplary abdominal free-breathing data obtained with the exemplary 3D GRE sequence at 0.55 Tesla according to exemplary embodiments of the present disclosure;

FIGS. 11(a)-11(d) are a set of images/maps with associated exemplary graphs providing exemplary results which utilize exemplary calculation of composite images based on the signal-response curves according to exemplary embodiments of the present disclosure;

FIG. 12 is a set of illustration providing examples for the quantitative estimation of the fat fraction in a phantom;

FIG. 13(a) is an exemplary neck scan image (e.g., FS image) acquired with a radial 3D spoiled-GRE sequence at 3 T using conventional spectral fat-saturation method;

FIG. 13(b) is an exemplary composed fat-suppressed image (e.g. FS image) obtained with the exemplary frequency-sweep RF saturation according to exemplary embodiments of the present disclosure;

FIG. 13(c) is an exemplary graph providing exemplary signal response curves of two exemplary ROIs in fat (red) and water (blue) tissues in the neck according to exemplary embodiments of the present disclosure;

FIG. 13(d) is an exemplary estimated B0 inhomogeneity dB0 map generated using a two-component model according to exemplary embodiments of the present disclosure;

FIG. 13(e) is an exemplary map of fitted center frequency b according to exemplary embodiments of the present disclosure;

FIG. 13(f) is an exemplary map of corrected center frequency b-dB0 according to exemplary embodiments of the present disclosure;

FIG. 14(a) is an exemplary composed fat-suppressed image from a 3 T neck scan (TE=1.73 ms) according to exemplary embodiments of the present disclosure;

FIG. 14(b) is an exemplary graph providing an exemplary signal-response curve of an ROI containing fat and water according to exemplary embodiments of the present disclosure;

FIG. 14(c) is an exemplary frequency-resolved reconstruction frame according to exemplary embodiments of the present disclosure;

FIG. 14(d) is an exemplary graph providing exemplary signal-response curves of an ROI containing fat and water according to exemplary embodiments of the present disclosure; and

FIG. 15 is a block diagram of an exemplary embodiment of a system according to the present disclosure.

Throughout the drawings, the same reference numerals and characters, unless otherwise stated, are used to denote like features, elements, components, or portions of the illustrated embodiments. Moreover, while the present disclosure will now be described in detail with reference to the figures, it is done so in connection with the illustrative embodiments and is not limited by the particular embodiments illustrated in the figures and appended claims.

### DETAILED DESCRIPTION OF THE EXEMPLARY EMBODIMENTS

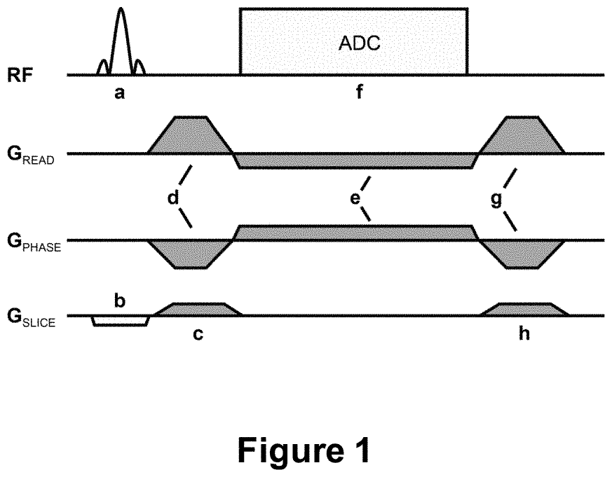

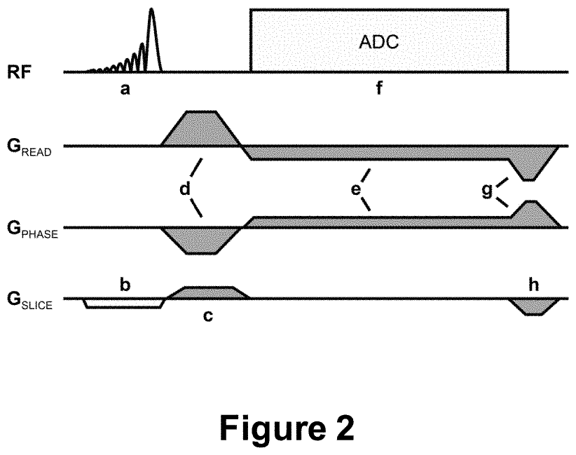

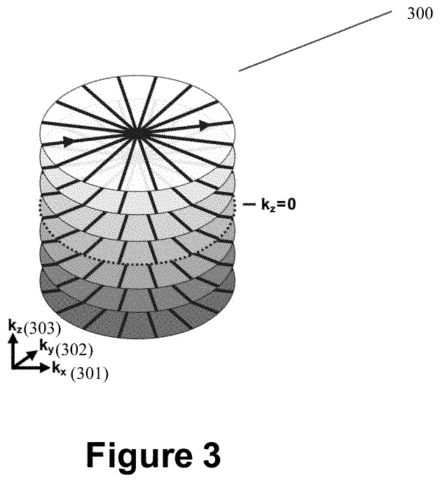

The exemplary systems, methods and computer-accessible medium according to an exemplary embodiment of the present disclosure have been implemented and demonstrated on a prototypic low-field whole-body MRI system with a magnetic field strength of 0.55 Tesla for two different MRI sequence types: 1) three-dimensional balanced steady-state free precession (bSSFP) acquisition (see FIGS. 1), and 2) three-dimensional spoiled gradient-recalled echo (GRE) acquisition (see FIG. 2). Both sequences can use the stack-of-stars geometry to acquire the k-space data, which uses radial sampling in the kx/ky plane with golden-angle ordering of the radial views and regular Cartesian sampling in the kz dimension (see FIG. 3). The underlying MRI sequences have been implemented following the description provided in (See, e.g., Block-2014) and have been extended with the proposed method for fat and water separation.

FIG. 1 shows an exemplary pulse sequence diagram of the exemplary 3D bSSFP MRI sequence with radial sampling according to exemplary embodiments of the present disclosure. In particular, the graphs of FIG. 1 illustrate an excitation pulse with flip-angle ±α (e.g., ±70 deg)—a, a slab-selection gradient—b, a slab-selection rewinder gradient—c, prephase gradients—d, readout gradients—e, data acquisition—f rewinder gradients—g, and a slab-selection prephase gradient—h. For exemplary radial sampling, the amplitude of gradients d, e, g can be modulated, e.g., according to G_READ=sin(φ), G_PHASE=cos(φ) where φ is the angle of the radial view.

FIG. 2 shows an exemplary pulse sequence diagram of an exemplary 3D GRE Mill sequence with radial sampling according to exemplary embodiments of the present disclosures. As illustrated in FIG. 2, the elements provided are as follows: an excitation pulse with flip angle α (e.g., 12 deg)—a, a slab-selection gradient—b, a slab-selection rewinder gradient—c, prephase gradients—d, readout gradients—e, data acquisition—f spoiler gradients—g and h. For radial sampling, the amplitude of gradients d, e, g can be modulated according to G_READ=sin(φ), G_PHASE=cos(φ), where φ is the angle of the radial view.

FIG. 3 illustrates an exemplary stack-of-stars acquisition scheme 300, which can utilize a radial sampling in the kx (301) and ky (302) plane and regular Cartesian sampling in the kz (303) direction according to exemplary embodiments of the present disclosure. For example, exemplary sampling procedures along kz can be performed sequentially for one radial angle φ (either with linear ordering from −kz,max to +kz,max, or with center-out ordering starting at kz=0). Thereafter, the views for the next angle can be acquired. The golden-angle scheme can be used for selecting the radial angle φ, which starts at φ=0 deg and adds Δφ=111.25 deg for each following angle.

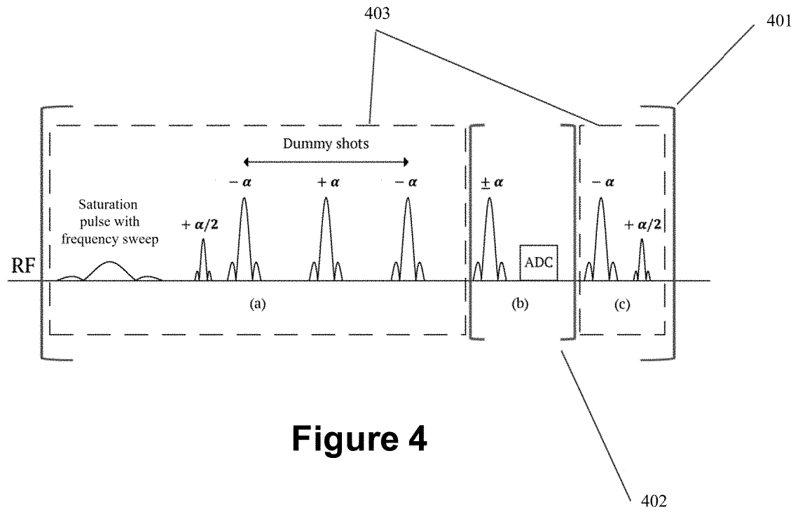

An exemplary RF saturation block has been integrated in the exemplary embodiment of the present disclosure, which can include a spectrally selective RF saturation pulse and spoiler gradient. For example, an adiabatic RF pulse with a hyperbolic secant waveform has been used, similar to the pulse used for regular SPAIR fat suppression. The saturation module can be executed prior to acquisition of each stack of radial views, e.g., once for every angle of radial spokes. In the case of the bSSFP sequence, the saturation block can be followed by one α/2 preparation and multiple dummy pulses to establish steady state (FIG. 4). After the bSSFP readout train, a flip-back module is played to store the transverse magnetization into the longitudinal plane before repeating the fat saturation module.

FIG. 4 illustrates an exemplary graph of timing of the RF pulses used for the 3D bSSFP sequence according to exemplary embodiments of the present disclosure. Outer brackets 401 indicate the outer loop over different radial angles, and inner brackets 402 indicate the inner loop over kz sampling positions. Dashed boxes 403 indicate the implemented fat-saturation module (a) RF saturation module comprising a SPAIR pulse, an α/2 preparation pulse, and three dummy shots; (b) bSSFP readout module; and (c) flip-back module. The exemplary frequency offset of the SPAIR pulse is modified after a user-selectable number of repetitions of the outer loop.

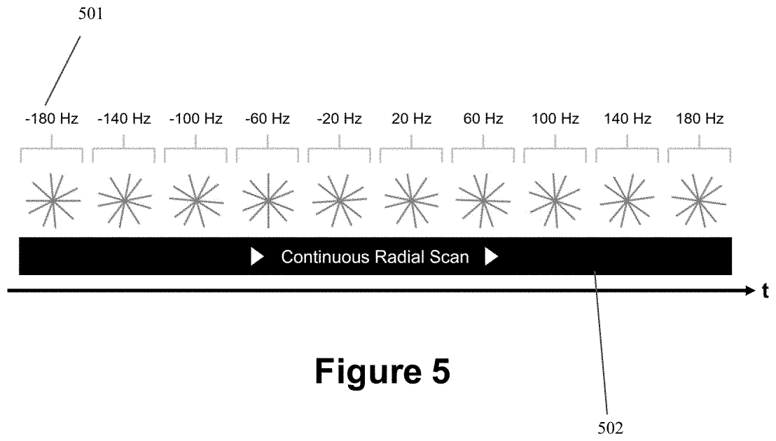

During an exemplary execution of either sequence type (bSSFP or GRE), the frequency offset of the RF saturation pulse can be changed in user-selectable increments (e.g., 40 Hz) starting from a user-selectable initial offset (e.g., −180 Hz) (see FIG. 5). A user-selectable number of readout steps is acquired for each offset (e.g., 100 radial views per increment), and the sequence is repeated until a user-selectable total number of radial views has been acquired (e.g., 1000 radial views in total). Data for the different frequency offsets can be acquired either with monotonously increased or with interleaved ordering of the offset frequency.

FIG. 5 shows an exemplary illustration of the frequency sweep RF saturation principle. The frequency offset of the RF saturation pulse 501 can be modified each time after a user-selectable number of outer sequence repetitions has been reached (e.g., 100 radial views) while a continuous radial acquisition 502 according to the golden-angle scheme is performed. Because all segments may use different radial angles, the whole data can be combined into a densely sampled average dataset, which can be used to estimate coil sensitivity profiles. By sorting the data according to the frequency offset and using it as additional dimension, the tissue response to the different saturation frequencies can be analyzed.

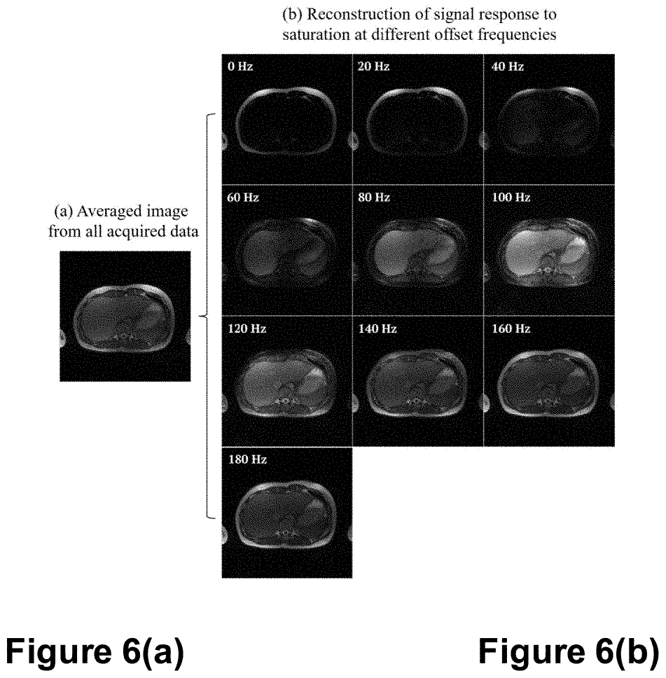

In example embodiments of the present disclosure, after data acquisition, averaged images can be reconstructed by combining all acquired data into a single dataset and performing a standard gridding reconstruction (see FIG. 6a). The averaged images can be used to provide immediate feedback to the operator of the MRI system and to estimate sensitivity profiles of the receive RF coils using the method described in (See, e.g., Walsh-2000). Afterwards, a compressed-sensing reconstruction can be performed by sorting and binning the acquired data according to the frequency offset of the RF saturation pulse and reconstructing a four-dimensional image matrix m(x,y,z,f) by solving the following inverse problem:

$$m ( x , y , z , f ) = {argmin}_{m} ( \frac{1}{2} {\sum }_{f} {‖ A \cdot C \cdot {m}_{f} - {d}_{f} ‖}_{2}^{2} + λ \cdot P ( m ) ) ,$$

where m is the to-be-estimated four-dimensional image with the fourth dimension f corresponding to the frequency offset, C denotes an operator that multiplies the image with the estimated coil sensitivity profiles, A denotes the forward operator that performs a fast Fourier transformation and gridding-based interpolation to the k-space sampling locations used for the frequency offset f, d denotes the experimentally acquired MRI data, P(m) denotes a penalty or regularization function, and λ denotes a scaling factor that needs to be adjusted depending on the specific penalty function. The following two penalty functions can be used for recovering the image set m from incomplete data y:

P₁(m)=Σ_{f}∥(m_{f}−m_{f-1})∥₁,

P₂(m)=Σ_{f}∥(m_{f}−m_{f-1})∥₂,

which correspond to the L1 and L2 norms of the finite differences in image space between adjacent frequency offsets. A solution to the inverse problem is found with a numerical optimization technique, such as the iterative non-linear conjugate gradient method, either by using a predefined number of iterations or running the iterations until a stopping criterion has been reached (Drawing 6b).

FIGS. 6(a) and 6(b) show a set of illustrations of an exemplary abdominal free-breathing scan with the 3D bSSFP sequence at 0.55 Tesla according to exemplary embodiments of the present disclosure. For example, FIG. 6(a) shows an exemplary average image obtained by reconstructing all data using standard gridding according to exemplary embodiments of the present disclosure. FIG. 6(b) illustrates an exemplary frequency-resolved reconstruction obtained by sorting the data according to the frequency offset and performing a compressed-sensing reconstruction according to exemplary embodiments of the present disclosure. The obtained image series shows the tissue response to the RF saturation pulses with different frequencies. It can be seen that fat and water respond at different frequencies.

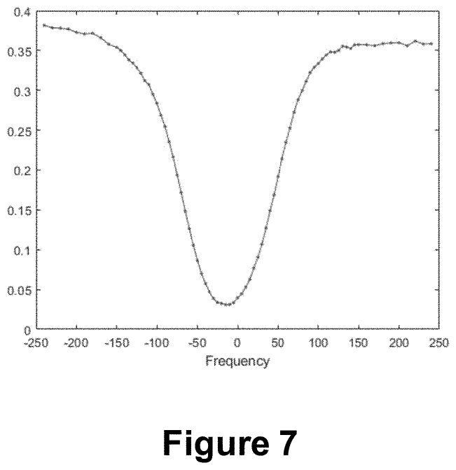

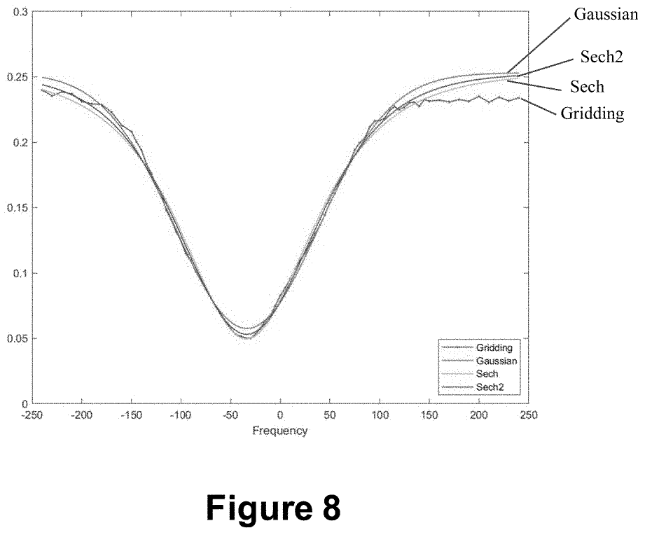

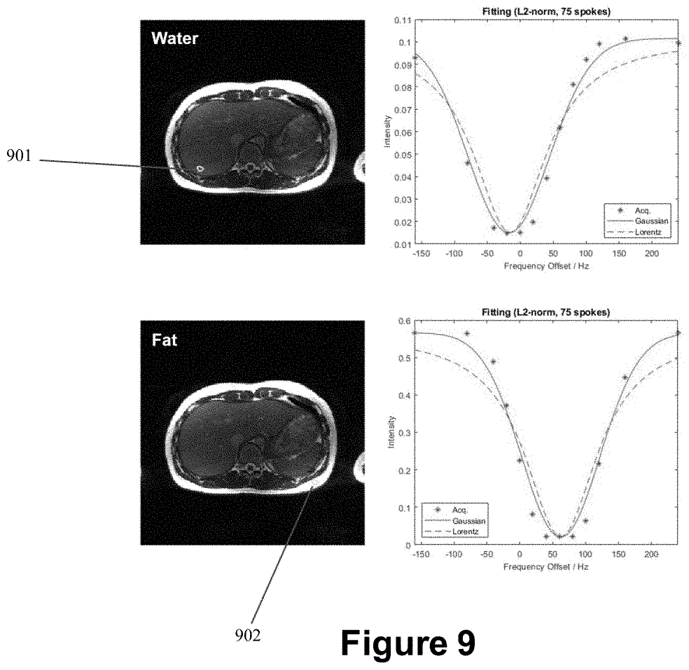

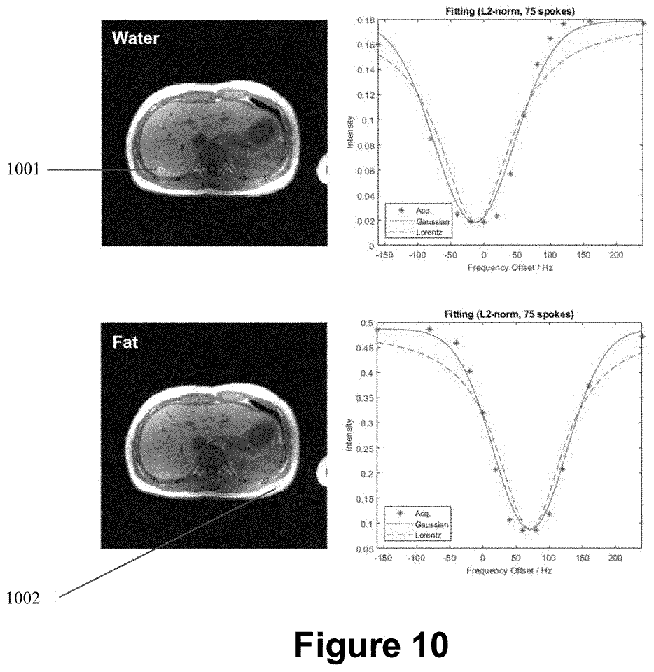

After the image matrix m has been reconstructed, signal-response curves can be extracted for each voxel (x,y,z): s_{x,y,z}(f)=m(x, y, z, f), and processed to determine the fat content (see FIG. 7). Because only a limited number of sampling points may be acquired during clinical imaging protocols, curve fitting can be used for analyzing the data. Different equations that resemble the spectral footprint of the RF saturation pulse may be used for the curve fitting, including Gaussian, Lorentzian, and hyperbolic secant functions (see FIG. 8). Because a hyperbolic secant waveform is used for the saturation pulse, using a hyperbolic secant function is preferred: s(f)=a·sech(f−b)+c, where a, b, c are variables that can be estimated during the fitting procedure. Variable b, which describes the center frequency of the fitted response curve, can then be used to classify the voxel content into predominantly fat or predominantly water and can be used to create binary fat/water maps (FIGS. 9 and 10).

FIG. 7 shows an exemplary graph with an exemplary signal-response curve extracted from the voxel of a phantom scan according to exemplary embodiments of present disclosure. In the exemplary phantom scan, a large number of sequence repetitions with small step-width were used for illustration purpose. For example, 125 radial views were each acquired for 79 different offset frequencies, ranging from −240 Hz to +240 Hz. A step width of 10 Hz was used between −240 Hz and −160 Hz as well as between +160 Hz and +240 Hz; a step width of 5 Hz was used between −150 Hz and +150 Hz.

FIG. 8 is an exemplary graph providing exemplary results of analytic equations that can be used for fitting the experimental data according to exemplary embodiments of the present disclosure. The exemplary equations can include the Gaussian function

$$s ( f ) = a \cdot exp ( - \frac{{( f - b )}^{2}}{2 {d}^{2}} ) + c ,$$

Lorentzian function

$$s ( f ) = a \cdot \frac{1}{π} \cdot \frac{\frac{1}{2} d}{{( f - b )}^{2} + {( \frac{1}{2} d )}^{2}} + c ,$$

and hyperbolic secant function

$$s ( f ) = a \cdot sec h ( f - b ) + c where sec h ( x ) = \frac{2}{exp ( x ) + exp ( - x )} .$$

The latter may perform best because the RF pulse waveform is also based on a hyperbolic secant function.

FIG. 9 shows exemplary illustrations and associated graphs providing exemplary abdominal free-breathing data obtained with the 3D bSSFP sequence at 0.55 Tesla according to exemplary embodiments of the present disclosure. For example, the data compares the signal-response curves obtained for a region-of-interest 901, 902 (indicated in yellow) with water (top) and with fat (bottom). It can be seen that the curves are shifted, so that the center position of the fitted function can be used as criterion for distinguishing between fat and water.

FIG. 10 exemplary illustrations and associated graphs providing exemplary abdominal free-breathing data obtained with the 3D GRE sequence at 0.55 Tesla according to exemplary embodiments of the present disclosure. The data compares the signal-response curves obtained for a region-of-interest 1001, 1002 (indicated in yellow) with water (top) and with fat (bottom). It can be seen that the curves are shifted, so that the center position of the fitted function can be used as criterion for distinguishing between fat and water.

As another exemplary procedure after analysis of the signal-response curves, the image information can be combined into water-only and fat-only composite images (Drawing 11). Different approaches can be used to generate the composite images, including masking of the initially calculated averaged images according to the binary fat/water maps, or by voxel-wise selection of the frequency offset with minimum fat signal and maximum water signal (and vice versa).

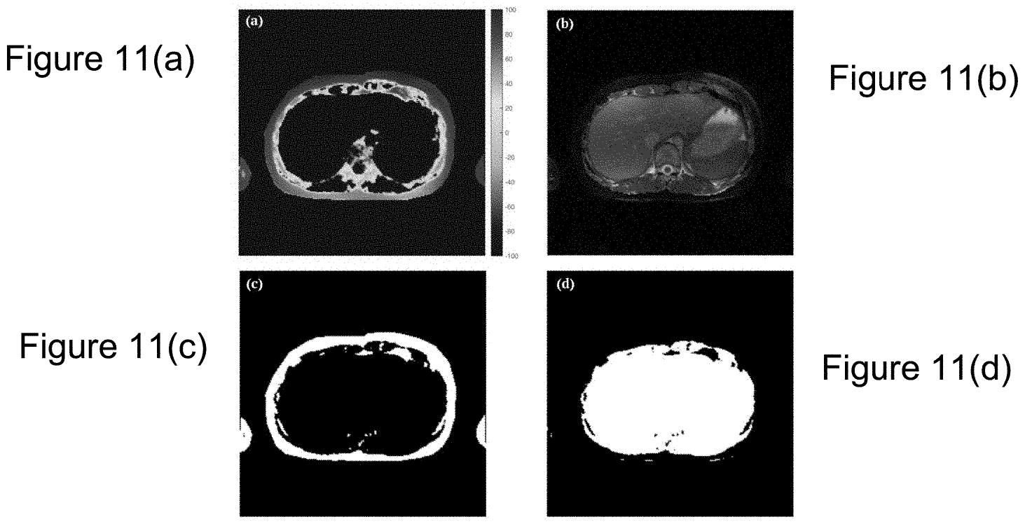

FIGS. 11(a)-11(d) show exemplary illustration of maps which are based on exemplary calculation of composite images based on the signal-response curves according to exemplary embodiments of the present disclosure. For example, FIG. 11(a) illustrates an exemplary map of fitted frequency shift b, shown in a color scale from −100 Hz to +100 Hz. FIG. 11(b) shows an exemplary fat-suppressed water-only composite image, generated voxel-by-voxel by taking the maximum value along the frequency-offset dimension for voxels classified as water and the minimum value for voxels classified as fat:

$$I\_water ( x , y , z ) = \{ \begin{matrix}max ( s ( f ) ) & if class ( x , y , z ) = wate r \\ min ( s ( f ) ) & if class ( x , y , z ) = fat\end{matrix}$$

where the classification into fat and water is based on the frequency shift b of the function fitted to the signal response function:

$$class ( x , y , z ) = \{ \begin{matrix}water & if b ( x , y , z ) < 50 Hz \\ fat & if ( x , y , z ) \geq 50 Hz\end{matrix} .$$

FIG. 11(c) illustrates an exemplary estimated fat map from such classification. FIG. 11(d) shows an exemplary estimated water map from this exemplary classification.

For quantitative estimation of the fat and water content, the equation that can be fitted to the signal-response curves is replaced by a two-component model that superimposes the contributions from fat and water:

s(f)=a·r·sech(f−b+Δw)+a·(1−r)·sech(f−b)+c,

where a, b, c, r are the variables that are estimated during the fitting procedure and Δw is the fixed chemical-shift distance at the magnetic field strength of the MRI system. Variable r describes the fraction of fat in the voxel, b describes shifts of the curve due to local B0 inhomogeneities, a and c are scaling factors. By voxel-wise fitting of the function (Drawing 12), spatial maps of the fat fraction and of the B0 inhomogeneity can be obtained from variables r and b. Because the B0 field strength is expected to change only smoothly, neighborhood relationships can be utilized for improving the robustness of the estimation procedure. For example, if estimating the maps simultaneously for all voxels, smoothness constraints can be imposed on the B0 map, leading to improved conditioning of the problem. Moreover, if an existing B0 map can be provided, e.g., from a calibration scan, it can be incorporated to stabilize the estimation of the fat fraction.

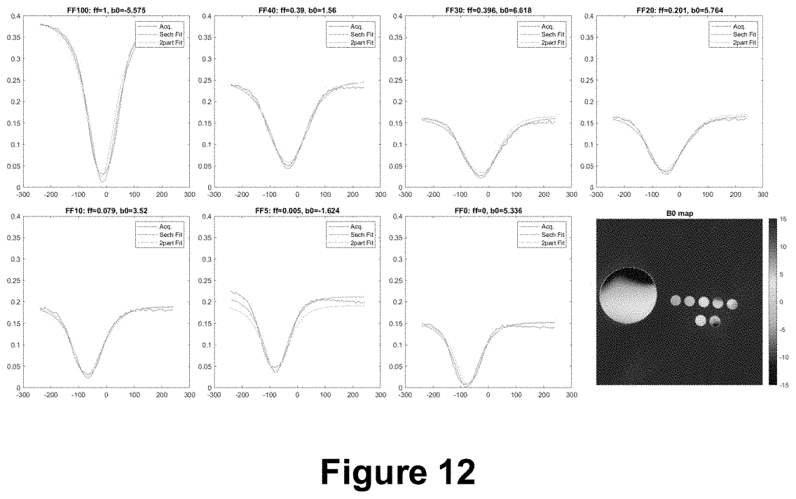

FIG. 12 shows exemplary graphs (and associated exemplary maps) for the quantitative estimations of the fat fraction in a phantom consisting of 7 small tubes with fat fractions ranging from 100% (FF100) to 0% (FF0). Signal-response curves were extracted from region-of-interests in the 7 tubes and used to fit a two-component model for estimating the fat fraction (ff) and B0 inhomogeneity (b0). The B0 map estimated from all voxels is shown on the bottom right.

### Exemplary Application(s) at Higher Field Strengths

While some fat-saturation techniques can perform generally well at regular clinical field strengths of 1.5 T or 3 T due to the large spectral distance of water and fat, fat saturation can be problematic in the proximity of skin folds, such as in neck or breast imaging where skin folds cause local inhomogeneities of the B0 field. This problem can be addressed using the exemplary frequency-sweep RF saturation principle, procedure and configuration according to exemplary embodiments of the present disclosure, which can be inherently insensitive to local B0 field inhomogeneities.

To demonstrate the exemplary benefits of the exemplary procedure, a neck scan was performed in a healthy volunteer at 3 T (MAGNETOM Prisma, Siemens Healthcare, Erlangen, Germany) using a 20-channel head/neck coil array. The data was acquired using a radial stack-of-stars 3D spoiled GRE sequence with a chemical-shift selective suppression (CHESS) pulse. Indeed, the frequency offset of the CHESS pulse was swept from −930 Hz to 510 Hz. 46 projection angles were acquired per frequency offset, resulting in 598 projection angles for the whole scan. Relevant parameters included: FOV 250×250×288 mm³, 11.1% slice oversampling, 6/8 slice partial Fourier, FA 12°, TR/TE 3.85/1.75 ms, BW 890 Hz/px, 1×1×2 mm³ resolution, 4:15 min total scan time. For comparison, a scan was collected using conventional fat saturation with the same number of projection angles and scan time.

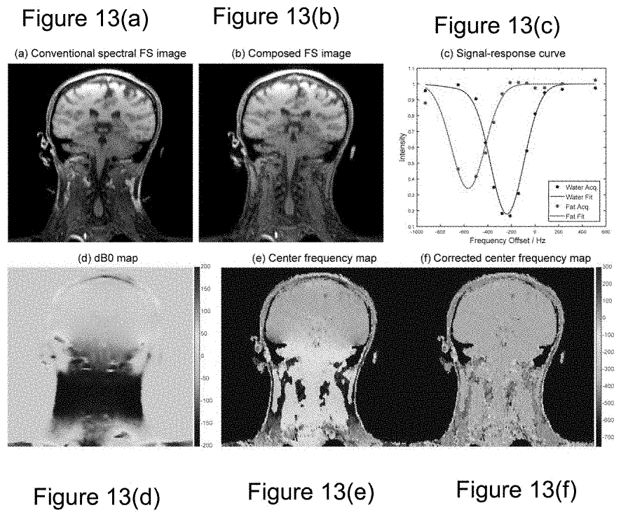

FIG. 13(a) shows an exemplary neck scan acquired with a radial 3D spoiled-GRE sequence at 3 T using conventional spectral fat-saturation method, which shows residual fat signal (red arrows) and suppressed water signal (blue arrows) due to local B0 inhomogeneities. FIG. 13(b) illustrates an exemplary composed fat-suppressed image obtained with the exemplary frequency-sweep RF saturation according to exemplary embodiments of the present disclosure. FIG. 13(c) shows a graph with the exemplary signal response curves of two exemplary ROIs in fat (red) and water (blue) tissues in the neck, which are shifted away from the nominal Larmor frequency, according to exemplary embodiments of the present disclosure. FIG. 13(d) illustrates an exemplary estimated B0 inhomogeneity dB0 map using a two-component model according to exemplary embodiments of the present disclosure. FIG. 13(e) shows an exemplary map of a fitted center frequency b according to exemplary embodiments of the present disclosure. FIG. 13(f) illustrates an exemplary map of a corrected center frequency b-dB0 according to exemplary embodiments of the present disclosure.

In particular, the limitation of conventional spectral fat-suppressed neck imaging at 3 T shown in FIG. 13(a) occurs because the fat and water resonances drift from the nominal Larmor frequency due to local B0 inhomogeneities, which is also seen in the two exemplary signal-response curves of FIG. 13(c) and the exemplary spatial map of the fitted center frequency of FIG. 13(e) obtained using the proposed frequency sweeping procedures according to exemplary embodiments of the present disclosure. The dB₀ field map was obtained by performing two-component model fitting and shows a strong B0 drift in the back of the neck as illustrated in FIG. 13(d). After correcting the center frequency using the dB₀ field map, the fat and water tissues show more consistent values around the chemical shift and 0, respectively, demonstrating the accuracy of the estimated of dB₀ field map. As result, the method/procedure according to the exemplary embodiments of the present disclosure can provide a consistent fat suppression in the neck—as shown in FIG. 13(b).

### Exemplary Inclusion of Signal Phase from Different Chemical Components

To improve the accuracy of the fat/water quantification as described herein, the phase difference between fat and water can be incorporated into an exemplary extended two-component fitting model:

$$s ( f ) = {a}_{F} \cdot sec h ( \frac{f - {db}_{0} + Δ w}{{c}_{F}} ) \cdot {e}^{i 2 πΔ w \cdot TE} + {a}_{W} \cdot ( \frac{f - {db}_{0}}{{c}_{W}} ) + d ,$$

whereas the fat intensity (a_{F}), water intensity (a_{w}), overall curve-shift from local B0 inhomogeneities (db₀), and residual noise (d) are the to-be-estimated variables during the fitting procedure. Δw is the fixed chemical-shift distance at the magnetic field strength of the MRI system. c_{F} and c_{W} are scaling factors for fat and water, reflecting the width of the signal-response curve, which can be estimated from calibration scans in a PDFF phantom. By voxel-wise fitting of the function, exemplary spatial maps of the fat fraction and of the B0 inhomogeneity can be obtained from variables a_{F}, a_{W}, and db₀. Because the B0 field map is expected to change only smoothly, neighborhood relationships can be utilized for improving the robustness of the estimation procedure, e.g., applying a smoothing filter on the voxel-wise fitted B0 field map and using it as initial value to repeat the fitting procedure.

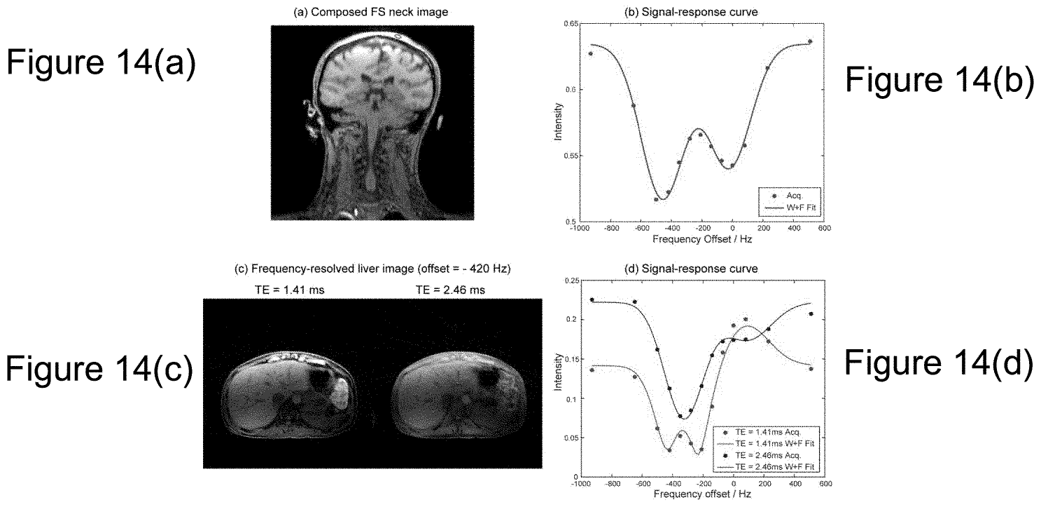

The inclusion of the phase difference between fat and water into the fitting equation can be performed and/or utilized, e.g., at high field strength because the shortest feasible echo time (TE) at 3 T usually results in an echo time near the opposed-phase condition. Due to the larger spectral distance between fat and water at 3 T, the signal response curves of voxels containing both fat and water can, therefore, have two local minima and show different shapes for different TE values (as shown in FIGS. 14(a)-14(d)). Thus, the exemplary two-component fitting can provide a more accurate estimation of the water and fat content, e.g., by taking the phase difference into account. An alternative way to address the phase differences can be to, e.g., incorporate the fitting model into the optimization problem of the frequency-resolved iterative reconstruction, generating fat and water images and the B0 field map directly from the k-space data.

For example, FIG. 14(a) shows an exemplary composed fat-suppressed image from a 3 T neck scan (TE=1.73 ms) according to exemplary embodiments of the present disclosure. FIG. 14(b) illustrates a graph providing an exemplary signal-response curve of an ROI containing fat and water according to exemplary embodiments of the present disclosure. FIG. 14(c) shows an exemplary frequency-resolved reconstruction frame with frequency offset of −420 Hz from a 3 T liver scan with TE=1.41 ms (close to opposed-phase time) and TE=2.46 ms (in-phase time) according to exemplary embodiments of the present disclosure. FIG. 14(d) illustrates a graph with exemplary signal-response curves of an ROI containing fat and water according to exemplary embodiments of the present disclosure. In accordance with the exemplary embodiments of the present disclosure, the exemplary local minima are visible in the signal-response curves, which are represented accurately when including the phase difference between fat and water into the exemplary two-component fitting model.

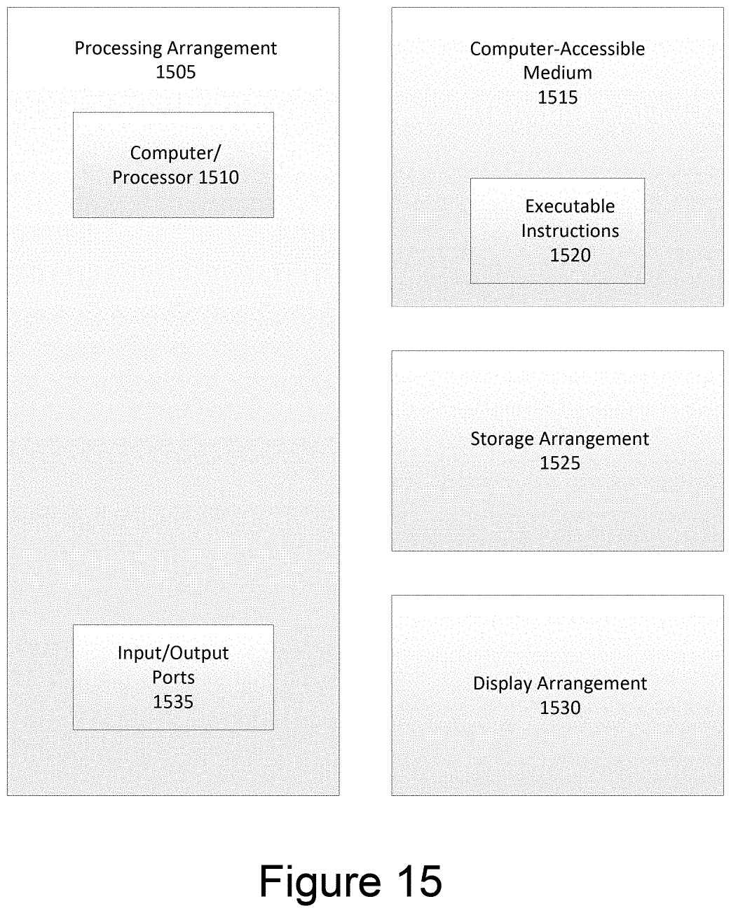

FIG. 15 shows a block diagram of an exemplary embodiment of a system according to the present disclosure. For example, exemplary procedures in accordance with the present disclosure described herein can be performed by a processing arrangement and/or a computing arrangement (e.g., computer hardware arrangement) 1505. Such processing/computing arrangement 1505 can be, for example entirely or a part of, or include, but not limited to, a computer/processor 1510 that can include, for example one or more microprocessors, and use instructions stored on a computer-accessible medium (e.g., RAM, ROM, hard drive, or other storage device).

As shown in FIG. 15, for example a computer-accessible medium 1515 (e.g., as described herein above, a storage device such as a hard disk, floppy disk, memory stick, CD-ROM, RAM, ROM, etc., or a collection thereof) can be provided (e.g., in communication with the processing arrangement 1505). The computer-accessible medium 1515 can contain executable instructions 1520 thereon. In addition or alternatively, a storage arrangement 1525 can be provided separately from the computer-accessible medium 1515, which can provide the instructions to the processing arrangement 1505 so as to configure the processing arrangement to execute certain exemplary procedures, processes, and methods, as described herein above, for example.

Further, the exemplary processing arrangement 1505 can be provided with or include an input/output ports 1535, which can include, for example a wired network, a wireless network, the interne, an intranet, a data collection probe, a sensor, etc. As shown in FIG. 15, the exemplary processing arrangement 1505 can be in communication with an exemplary display arrangement 1530, which, according to certain exemplary embodiments of the present disclosure, can be a touch-screen configured for inputting information to the processing arrangement in addition to outputting information from the processing arrangement, for example. Further, the exemplary display arrangement 1530 and/or a storage arrangement 1525 can be used to display and/or store data in a user-accessible format and/or user-readable format.

The foregoing merely illustrates the principles of the disclosure. Various modifications and alterations to the described embodiments will be apparent to those skilled in the art in view of the teachings herein. It will thus be appreciated that those skilled in the art will be able to devise numerous systems, arrangements, and procedures which, although not explicitly shown or described herein, embody the principles of the disclosure and can be thus within the spirit and scope of the disclosure. Various different exemplary embodiments can be used together with one another, as well as interchangeably therewith, as should be understood by those having ordinary skill in the art. In addition, certain terms used in the present disclosure, including the specification, drawings and claims thereof, can be used synonymously in certain instances, including, but not limited to, for example, data and information. It should be understood that, while these words, and/or other words that can be synonymous to one another, can be used synonymously herein, that there can be instances when such words can be intended to not be used synonymously. Further, to the extent that the prior art knowledge has not been explicitly incorporated by reference herein above, it is explicitly incorporated herein in its entirety. All publications referenced in this document are incorporated herein by reference in their entireties.

### Exemplary References

The following references are hereby incorporated by reference, in their entireties:

1. Bieri O, Scheffler K. Fundamentals of balanced steady state free precession MRI. J Magn Reson Imaging. 2013;38(1):2-11.

2. Bley T A, Wieben O, Francois C J, Brittain J H, Reeder S B. Fat and water magnetic resonance imaging. J Magn Reson Imaging. 2010;31(1):4-18.

3. Block K T, Uecker M, Frahm J. Undersampled radial MRI with multiple coils. Iterative image reconstruction using a total variation constraint. Magn Reson Med. 2007;57(6):1086-1098.

4. Block K T, Chandarana H, Milla S, Bruno M, Mulholland T, Fatterpekar G, Hagiwara M, Grimm R, Geppert C, Kiefer B, Sodickson D K. Towards Routine Clinical Use of Radial Stack-of-Stars 3D Gradient-Echo Sequences for Reducing Motion Sensitivity. J Korean Soc Magn Reson Med. 2014 Jun;18(2):87-106.

5. Chandarana H, Block T K, Rosenkrantz A B, et al. Free-breathing radial 3D fat-suppressed T1-weighted gradient echo sequence: a viable alternative for contrast-enhanced liver imaging in patients unable to suspend respiration. Invest Radiol. 2011;46(10):648-653.

6. Chandarana H, Bagga B, Huang C, et al. Diagnostic abdominal MR imaging on a prototype low-field 0.55 T scanner operating at two different gradient strengths. Abdom Radiol (NY). 2021;46(12):5772-5780.

7 Feng L, Grimm R, Block K T, et al. Golden-angle radial sparse parallel MRI: combination of compressed sensing, parallel imaging, and golden-angle radial sampling for fast and flexible dynamic volumetric MM. Magn Reson Med. 2014;72(3):707-717.

8. Feng L, Axel L, Chandarana H, Block K T, Sodickson D K, Otazo R. XD-GRASP: Golden-angle radial MM with reconstruction of extra motion-state dimensions using compressed sensing. Magn Reson Med. 2016;75(2):775-788.

9. Lauenstein T C, Sharma P, Hughes T, Heberlein K, Tudorascu D, Martin D R. Evaluation of optimized inversion-recovery fat-suppression techniques for T2-weighted abdominal MR imaging. J Magn Reson Imaging. 2008;27(6):1448-1454.

10. Lauterbur P C, Image Formation by Induced Local Interactions: Examples Employing Nuclear Magnetic Resonance. Nature 1973, 242, 190-191.

11. Liu Y, Leong A T L, Zhao Y, et al. A low-cost and shielding-free ultra-low-field brain MRI scanner. Nat Commun. 2021;12(1):7238.

12. Lustig M, Donoho D, Pauly J M. Sparse MRI: The application of compressed sensing for rapid MR imaging. Magn Reson Med. 2007;58(6):1182-1195.

13. Walsh D O, Gmitro A F, Marcellin M W. Adaptive reconstruction of phased array MR imagery. Magn Reson Med. 2000;43(5):682-690.

1. A method for separating fat from water contributions in at least one magnetic resonance (“MR”) image, comprising:
providing periodic RF saturation pulses with varying frequency offset from a water resonance frequency with at least two different offsets;
analyzing the signal response to saturation at different frequencies on a voxel-by-voxel basis; and
based on the analyzed signal response, separating the fat from the water contributions in the at least one MR image.

2. The method of claim 1, wherein the analyzing of the signal response comprises using a signal-response profile to classify each voxel into substantially containing fat and substantially containing water.

3. The method of claim 1, wherein the analyzing of the signal response comprises using a signal-response profile to quantitatively estimate a percentage of fat and a percentage of water contained in each voxel.

4. The method of claim 1, wherein the analyzing of the signal response comprises radial sampling of k-space to acquire data for different frequency offsets of the RF saturation pulse.

5. The method of claim 4, further comprising sampling radial views such that acquired view angles differ between frequency offsets and the radial views are combined to form a dense set of radial views.

6. The method of claim 1, wherein the analyzing of the signal response comprises under-sampling data for each frequency offset by skipping sampling steps to shorten an acquisition duration.

7. The method of claim 6, wherein the analyzing of the signal response comprises using a compressed-sensing principle to recover images for different frequency offsets by utilizing correlations between the data from adjacent frequency offsets.

8. The method of claim 1, wherein the analyzing of the signal response comprises using an XD-GRASP procedure and a compressed-sensing procedure for radial sampling to recover images for all frequency offsets.

9. The method of claim 8, wherein the offset frequency is treated as extra dimension for the XD-GRASP procedure.

10. The method of claim 8, further comprising performing a correlation of adjacent frequency offsets by penalizing an L1 norm or an L2 norm of the finite difference of the image intensity between a current frequency offset and at least one of the adjacent frequency offsets on a voxel-by-voxel basis.

11. The method of claim 5, wherein the analyzing of the signal response comprises combining the data acquired for the different frequency offsets into at least one of (i) a composite image that shows only water contributions, or (ii) a composite image that shows only the fat contributions.

12. The method of claim 5, wherein the analyzing of the signal response comprises fitting an analytical signal-response model to an experimentally observed signal-response curve to quantitatively estimate a fat fraction in each voxel.

13. The method of claim 5, wherein the analyzing of the signal response comprises fitting an analytical signal-response model to an experimentally observed signal-response curve to quantitatively and jointly estimate a fat fraction and a static magnetic field deviation B₀ in each voxel.

14. The method of claim 1, wherein the analyzing of the signal response comprises using neighborhood relationships to enforce smooth spatial change of an estimated static magnetic field deviation map B0.

15. The method of claim 1, wherein the separating procedure comprises calculating a phase difference between the fat and the water.

16. The method of claim 1, wherein the phase difference between the fat and the water is incorporated into an extended two-component fitting model.

17. The method of claim 16, wherein the extended two-component fitting model is based on at least one of a fat intensity or a water intensity.

18. The method of claim 16, wherein the extended two-component fitting model is based on at least an overall curve-shift from local B0 inhomogeneities or residual noise.

19. A system for separating fat from water contributions in at least one magnetic resonance (“MR”) image, comprising:
at least one computing processor which is configured to:
Cause periodic RF saturation pulses with varying frequency offset to be provided from a water resonance frequency with at least two different offsets;
analyze the signal response to saturation at different frequencies on a voxel-by-voxel basis; and
based on the analyzed signal response, separate the fat from the water contributions in the at least one MR image.

20. A non-transitory computer-accessible medium having stored thereon computer-executable instructions for separating fat from water contributions in at least one magnetic resonance (“MR”) image, wherein, when a computer arrangement executes the instructions, the computer arrangement is configured to perform procedures comprising:
causing periodic RF saturation pulses with varying frequency offset to be provided from a water resonance frequency with at least two different offsets;
analyzing the signal response to saturation at different frequencies on a voxel-by-voxel basis; and
based on the analyzed signal response, separating the fat from the water contributions in the at least one MR image.
